(19) United States
(12) Patent Application Publication
(10) Pub. No.: US 2012/0250269 A1
(43) Pub. Date: Oct. 4, 2012

(54) TELEVISION RECEIVER AND ELECTRONIC DEVICE

(75) Inventors: Akihiko HAPPOYA, Ome-shi (JP); Sadahiro TAMAI, Ome-shi (JP)

(73) Assignee: KABUSHIKI KAISHA TOSHIBA, Tokyo (JP)

(21) Appl. No.: 13/328,439

(22) Filed: Dec. 16, 2011

(30) Foreign Application Priority Data
Mar. 31, 2011 (JP) 2011-080618

(51) Int. Cl. H05K 1/02

(52) U.S. Cl. 361/749

(57) ABSTRACT

According to one embodiment, a television receiver includes a housing, a circuit board, and a flexible printed wiring board. The flexible printed wiring board is electrically connected to the circuit board, and includes an inner layer, a first outer layer, a second outer layer, a first conductive layer, a second conductive layer, and a conductive portion. The inner layer is provided with a first surface and a second surface. The first outer layer covers the first surface. The second outer layer covers the second surface. The first conductive layer is buried in the first surface and is in contact with the first outer layer. The second conductive layer is buried in the second surface and is in contact with the second outer layer. The conductive portion passes through the inner layer and electrically connects between the first conductive layer and the second conductive layer.

### CROSS-REFERENCE TO RELATED APPLICATIONS

This application is based upon and claims the benefit of priority from Japanese Patent Application No. 2011-080618, filed Mar. 31, 2011, the entire contents of which are incorporated herein by reference.

### FIELD

Embodiments described herein relate generally to a television receiver and an electronic device.

### BACKGROUND

There have been known flexible printed wiring boards having a base layer where a conductive layer is formed. Both surfaces of the base layer are coated with a coating layer.

It may be a troublesome process to coat both surfaces of the base layer, in which a conductive layer is formed, with a coating layer.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary front view of a television receiver according to a first embodiment;

FIG. 2 is an exemplary side view of the television receiver in the first embodiment;

FIG. 3 is an exemplary back view of the inside of the television receiver in the first embodiment;

FIG. 4 is an exemplary plan view of a flexible printed wiring board in the first embodiment;

FIG. 5 is an exemplary flowchart of the process of manufacturing the flexible printed wiring board in the first embodiment;

FIG. 6 is an exemplary cross-sectional view of the flexible printed wiring board in a manufacturing process where a conductive layer is formed on an outer layer in the first embodiment;

FIG. 7 an exemplary cross-sectional view of the flexible printed wiring board in the manufacturing process where etching is applied to the structure of FIG. 6 in the first embodiment;

FIG. 8 is an exemplary cross-sectional view of the flexible printed wiring board in the manufacturing process where a conductive portion is provided to a first outer layer in the structure of FIG. 7 in the first embodiment;

FIG. 9 is an exemplary cross-sectional view of the flexible printed wiring board in the manufacturing process where a base layer is bonded to the structure of FIG. 8 in the first embodiment;

FIG. 10 is an exemplary cross-sectional view of the flexible printed wiring board in the manufacturing process where a protective film is removed from the structure of FIG. 9 in the first embodiment;

FIG. 11 is an exemplary cross-sectional view of the flexible printed wiring board in the manufacturing process where a second outer layer is bonded to the structure of FIG. 10 in the first embodiment;

FIG. 12 is an exemplary cross-sectional view of the flexible printed wiring board obtained by the manufacturing process in the first embodiment;

FIG. 13 is an exemplary cross-sectional view of a flexible printed wiring board in a manufacturing process where a conductive layer is formed on a base layer via an adhesive layer according to a modification of the first embodiment;

FIG. 14 is an exemplary cross-sectional view of the flexible printed wiring board obtained by the manufacturing process in the modification of the first embodiment;

FIG. 15 is an exemplary cross-sectional view of a flexible printed wiring board in a manufacturing process where a protective film is provided to a base layer according to a second embodiment;

FIG. 16 is an exemplary cross-sectional view of the flexible printed wiring board in the manufacturing process where through holes are formed in the structure of FIG. 15 in the second embodiment;

FIG. 17 is an exemplary cross-sectional view of the flexible printed wiring board in the manufacturing process where a conductive portion is provided to one of the through holes in the structure of FIG. 16 in the second embodiment;

FIG. 18 is an exemplary cross-sectional view of the flexible printed wiring board in the manufacturing process where a protective film is removed from the structure of FIG. 17 in the second embodiment;

FIG. 19 is an exemplary cross-sectional view of the flexible printed wiring board in the manufacturing process where an outer layer is bonded to the structure of FIG. 18 in the second embodiment;

FIG. 20 is an exemplary cross-sectional view of the flexible printed wiring board obtained by the manufacturing process in the second embodiment; and

FIG. 21 is an exemplary perspective view of an electronic device according to a third embodiment.

### DETAILED DESCRIPTION

In general, according to one embodiment, a television receiver comprises a housing, a circuit board, and a flexible printed wiring board. The circuit board is housed in the housing. The flexible printed wiring board is electrically connected to the circuit board, and comprises an inner layer, a first outer layer, a second outer layer, a first conductive layer, a second conductive layer, and a conductive portion. The inner layer is provided with a first surface and a second surface located opposite the first surface. The first outer layer covers the first surface of the inner layer. The second outer layer covers the second surface of the inner layer. The first conductive layer is buried in the first surface of the inner layer and is in contact with the first outer layer. The second conductive layer is buried in the second surface of the inner layer and is in contact with the second outer layer. The conductive portion passes through the inner layer and electrically connects between the first conductive layer and the second conductive layer.

Exemplary embodiments will be described in detail below with reference to the accompanying drawings. In the following embodiments, like elements are designated by like reference numerals, and their description will not be repeated.

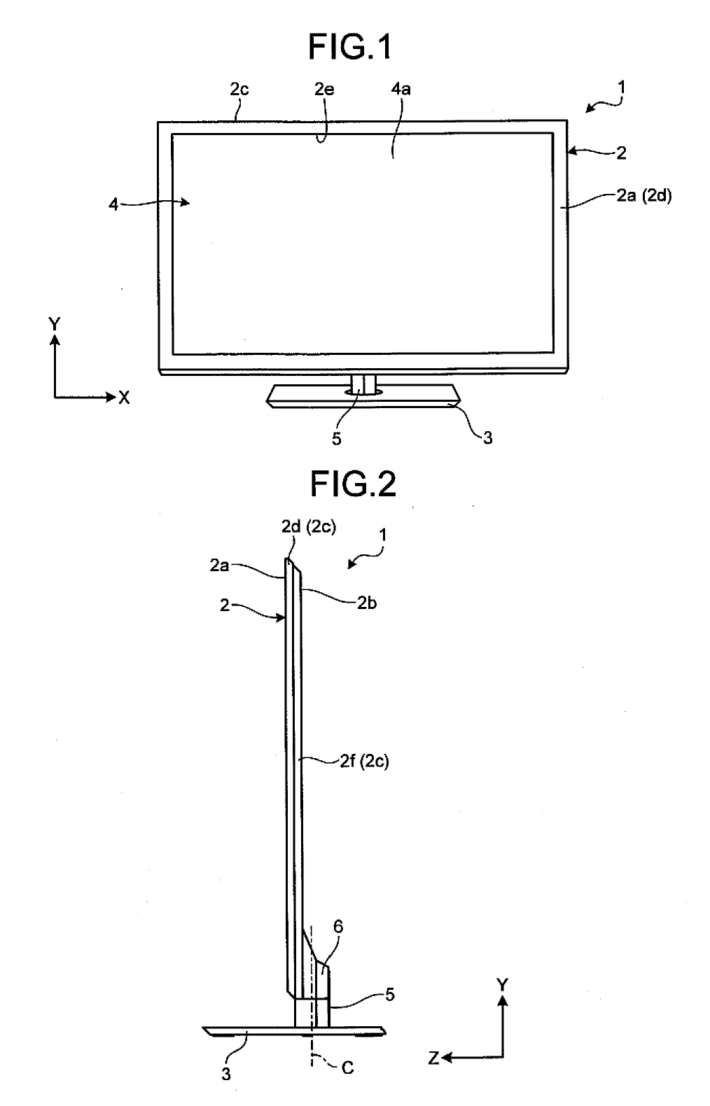

FIG. 1 illustrates a television (TV) receiver 1 according to a first embodiment. For the sake of convenience, directions are defined as follows: X direction indicates the right direction in the front view of the display screen of the TV receiver 1 (the left direction in the back view); Y direction indicates the up direction; and Z direction indicates the normal direction of the display screen.

As illustrated in FIGS. 1 and 2, in the first embodiment, the TV receiver 1 comprises a base 3 and a relatively thin flat rectangular main body 2. The main body 2 is supported on the base 3 via a leg 5 and an attachment portion 6. The main body 2 comprises a housing 2c having a front surface 2a provided with a rectangular opening 2e. The housing 2c houses therein a display module 4 (a display unit 8) having a display screen 4a that is exposed from the opening 2e. The display module 4 may be, for example, a liquid crystal display (LCD) panel or an organic electroluminescent display (GELD) panel. The display module 4 is an example of a display device, a display module, a module, and a panel.

For example, the housing 2c is formed of a combination of parts such as a front mask 2d on the front surface 2a side and a back cover 2f on the side of a back surface 2b. The attachment portion 6 protrudes from the back surface 2b toward the back, and is supported by the leg 5 to be rotatable about the rotation axis C. The front mask 2d may include part of the front wall and the side wall (circumferential wall, stand wall). The back cover 2f may include part of the back wall and the side wall. The front, side, and back walls are part of a wall section. Besides, as illustrated in FIG. 1, the housing 2c has four corners.

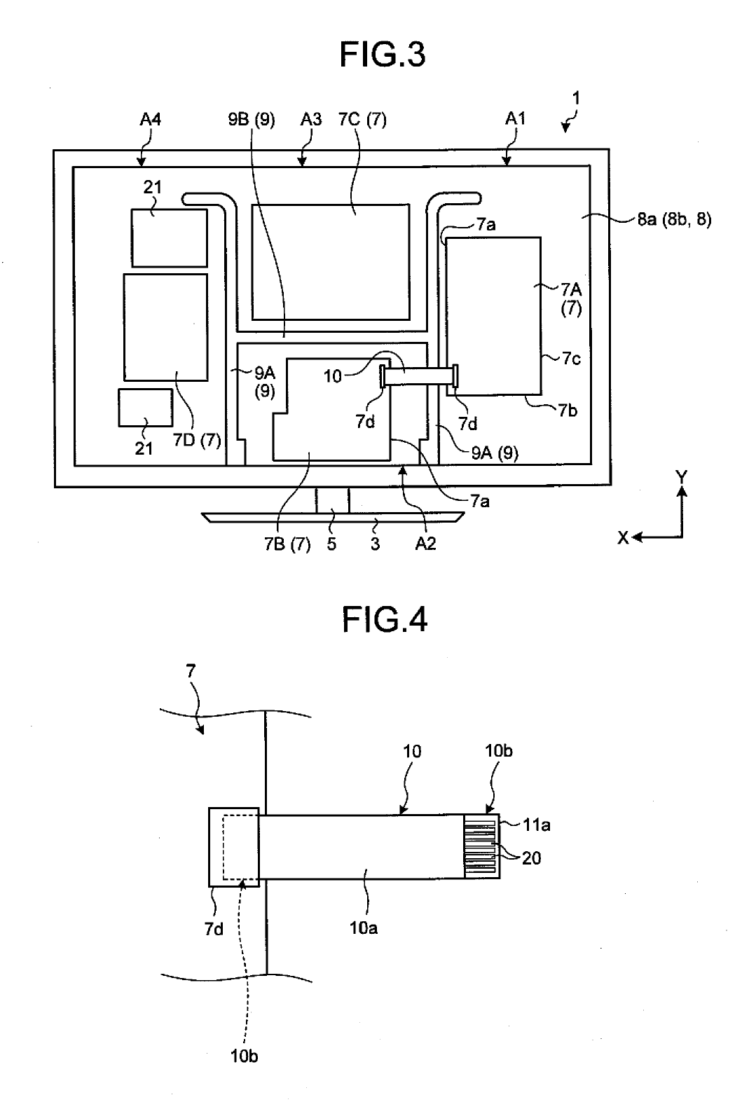

As illustrated in FIG. 3, a plurality of circuit boards 7 (7A to 7D) are attached by fasteners such as screws (not illustrated) onto a back surface 8a (i.e., a surface opposite the display screen 4a) of the display unit 8 including the displaymodule 4. The circuit boards 7 are each fixed on a boss (not illustrated) protruding on the back surface 8a. Thus, there is a space between the circuit boards 7 and the back surface 8a.

The back surface 8a of the display unit 8 corresponds to a back plate 8b as a wall that is provided with ribs 9 (9A, 9B). The ribs 9 (9A, 9B) are arranged in substantially an H-shape in the back view (i.e., in the view of FIG. 3) and protrude on the back surface 8a. The ribs 9A (first ribs) are spaced apart in the horizontal direction and extend in parallel along the vertical direction in the horizontal center of the back plate 8b. The rib 9B (second rib) is a bridge between the vertical centers of the two ribs 9A and extends in the horizontal direction. The ribs 9A and 9B are portions (reinforcement portions, framework) that structurally reinforce the display unit 8. The ribs 9A and 9B may be formed by partly bending the back plate 8b by pressing or the like, or by adding other parts. The ribs 9A and 9B may also be formed by partly bending the back plate 8b and then adding other parts. Any of the ribs 9 (e.g., the ribs 9A) is provided with a portion for VESA (registered trademark) mount, i.e., for wall hanging (e.g., a boss, a screw hole, etc., not illustrated).

As illustrated in FIG. 3, in the first embodiment, the ribs 9A and 9B arranged in an H-shape divide the back surface 8a of the display unit 8 into areas A1 to A4. In the back view, the area A1 is located on the right side of the right rib 9A, the areas A2 and A3 are located below and above the rib 9B, respectively, in the horizontal center, and the area A4 is located on the left side of the left rib 9A. The circuit boards 7A to 7D (printed circuit boards, printed wiring boards, wiring substrates, rigid flexible printed wiring boards, etc.), components 21, and the like are appropriately dispersed and installed in the areas A1 to A4.

For example, in the first embodiment, the circuit board 7A (first circuit board) is located in the area A1, the circuit board 7B (second circuit board) is located in the area A2, the circuit board 7C (third circuit board) is located in the area A3, and the circuit board 7D (fourth circuit board) is located in the area A4. The components 21 (modules such as a hard disk drive, a speaker, etc.) are also located in the area A4. Incidentally, each of the circuit boards 7 may be covered with a shield case (not illustrated).

The circuit boards 7 may be provided with, for example, an input signal processing circuit, a frame rate converter (FRC) circuit, a timing control (TCON) circuit, a driver (XY driver) circuit, and the like.

The input signal processing circuit comprises, for example, a tuner, a connector, and the like (all not illustrated). The input signal processing circuit processes a signal received from an audio visual (AV) device or the like, and outputs video data and audio data. The input signal processing circuit is capable of various types of video processing, correction, image synthesis, and the like.

The FRC circuit receives the video data from the input signal processing circuit and, for example, generates an interpolation frame from a motion vector of the video to convert the frame rate of the video. The FRC circuit is capable of three-dimensional (3D) video generation processing, high-definition processing, and the like. The FRC circuit outputs an increased amount of video data per unit time compared to input video data.

The TCON circuit receives the video data from the FRC circuit and generates a timing signal to control the driver circuit at the latter stage. The TCON circuit outputs the video data and the timing signal.

The driver circuit drives the display module 4, i.e., a plurality of thin film transistors (TFTs) of the display module 4, based on the signal received from the TCON circuit to display predetermined video on the display module 4.

In the first embodiment, for example, the circuit board 7A is provided with the input signal processing circuit, and the circuit board 7B is provided with the FRC circuit, the TCON circuit, and the like. In this case, as illustrated in FIG. 3, the circuit boards 7A and 7B are arranged on both sides of the right rib 9A, respectively.

In the first embodiment, for example, as illustrated in FIG. 3, the circuit boards 7A and 7B are electrically connected together via a flexible printed wiring board 10 (flexible printed wiring board, flexible printed circuits). As previously described, the right rib 9A is located between the circuit boards 7A and 7B, and the rib 9A protrudes backward. Accordingly, the space between the back plate 8b as a wall and the back cover 2f (see FIG. 2) as the back wall of the housing 2c is narrower than the space without the ribs 9. In the first embodiment, the data transfer amount between the circuit boards 7A and 7B is relatively small before being increased by the FRC circuit, and therefore the flexible printed wiring board 10 can be used as a cable to electrically connect the circuit boards 7A and 7B. Thus, according to the first embodiment, it is possible to suppress the influence of cables (the number, diameter, etc. of cables) on the thickness reduction of the housing 2c, improvement in the rigidity and the strength, and the like. In addition, it is possible to reduce the manufacturing process and cost compared to the case where the circuit boards are electrically connected by a larger number of twisted pair cables.

The circuit board 7A is provided with a plurality of connectors (for external connection, not illustrated) along the periphery (circumference, e.g., edges 7b and 7c illustrated in FIG. 3). With the structure in which the connectors are exposed from a space (opening) between the back cover 2f and the back plate 8b, if the circuit board 7A is located in the area A1, the edge (circumference, e.g., edges 7b and 7c illustrated in FIG. 3) of the circuit board 7A is likely to extend along the periphery of the back plate 8b. As a result, the space (opening) can be easily provided.

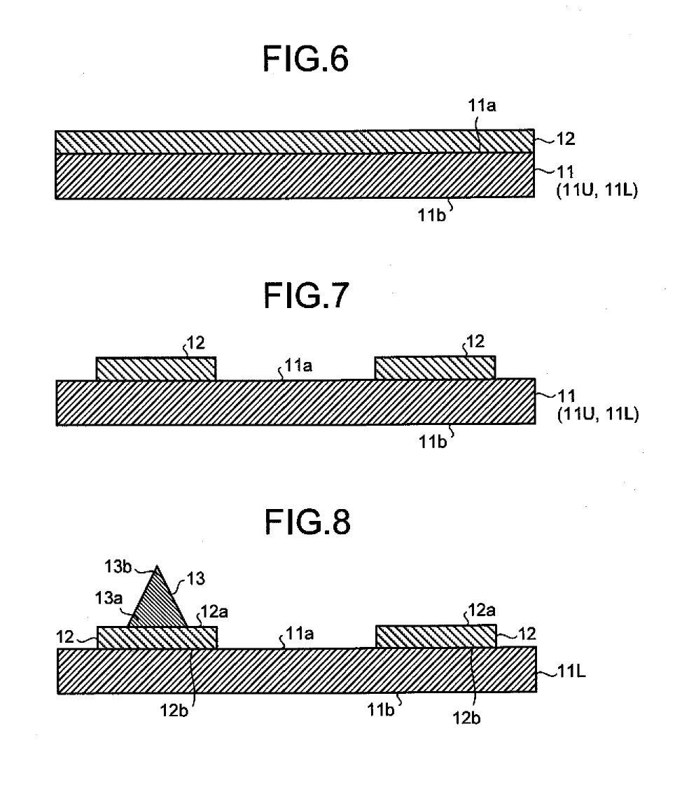

In the example of FIG. 4, the flexible printed wiring board 10 extends in a belt with a constant width. The flexible printed wiring board 10 has a long portion 10a and end portions 10b at the ends of the long portion 10a in the longitudinal direction. The end portions 10b are formed as connector portions where terminals 20 (connector terminals, connection points, contact points, conductors) are exposed. As illustrated in FIG. 3, the end portions 10b are inserted into and connected to connectors 7d near edges 7a of the circuit boards 7 (7A, 7B), respectively. The terminals 20 of the end portions 10b come in contact with terminals (not illustrated) of the connectors 7d, and conduction is established therebetween. Thus, conductors of the circuit boards 7A and 7B are electrically connected via the terminals 20 of the flexible printed wiring board 10, an internal conductive layer 12 (see FIG. 6, etc.), and the like.

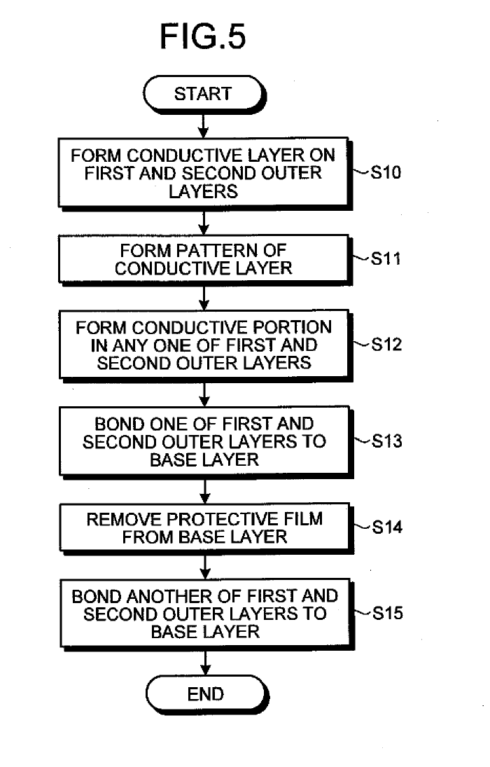

FIG. 5 is a flowchart of the process of manufacturing the flexible printed wiring board 10 according to the first embodiment. FIGS. 6 to 12 are cross-sectional views of the flexible printed wiring board 10 in the manufacturing process.

First, as illustrated in FIG. 6, the conductive layer 12 (wiring layer, second layer, second portion, second area) is formed on a first surface 11a and a second surface 11b of an outer layer 11 (first outer layer 11L, second outer layer 11U, cover, cover layer, upper layer, third layer, third portion, third area) (S10). The outer layer 11 may be made of, for example, an engineering plastic film (synthetic resin material) such as polyimide (PI), polyethylene terephthalate (PET), liquid crystal polymer (LCP), and the like. The outer layer 11 may also be made of prepreg. The outer layer 11 is an example of a coating layer, a protective layer, and an insulating layer. The conductive layer 12 may be made of, for example, copper foil. The conductive layer 12 may be formed on the surface (the first surface 11a and the second surface 11b) of the outer layer 11 by, for example, plating, sputtering, vapor deposition, adhesion, or the like. The conductive layer 12 formed on the first outer layer 11L is an example of a first conductive layer, while the conductive layer 12 formed on the second outer layer 11U is an example of a second conductive layer. The first outer layer 11L is an example of a cover, a cover layer, a second layer, a second portion, and a second area. The second outer layer 11U is an example of a cover, a cover layer, a third layer, a third portion, and a third area.

Next, as illustrated in FIG. 7, for example, etching is applied to the conductive layer 12 of FIG. 6 to form a pattern of the conductive layer 12 (conductive pattern, wiring pattern, wiring) on the first surface 11a of the outer layer 11 (S11).

Then, as illustrated in FIG. 8, a conductive portion 13 is provided on a first surface 12a of the conductive layer 12, i.e., the conductive layer pattern (S12). The conductive portion 13 may be a conductive bump (e.g., silver paste, copper paste, etc.). For example, the conductive portion 13 is a protrusion (e.g., conical protrusion) including a base portion 13a and a top (tip) portion 13b. The base portion 13a is located near the first surface 12a and is thick. The top portion 13b is separated from the first surface 12a and is thin. The first surface 12a is located opposite a second surface 12b which is in contact with the first surface 11a of the outer layer 11. While, in the first embodiment, the conductive portion 13 is described by way of example as being provided on the first outer layer 11L as the outer layer 11, it may be provided on the second outer layer 11U or on both the first outer layer 11L and the second outer layer 11U.

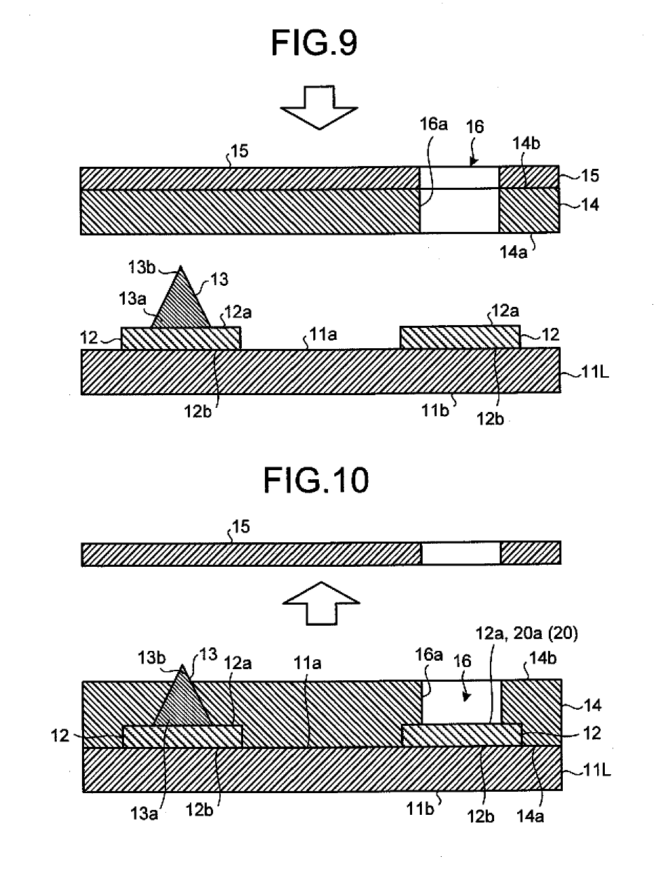

Thereafter, as illustrated in FIGS. 9 and 10, a base layer 14 (base, first layer, first portion, first area) is placed on the first surface 11a of the first outer layer 11L illustrated in FIG. 8 (S13). The base layer 14 is an example of an intermediate layer, an inner layer, an insulating layer, and a lower layer. The base layer 14 may be made of, for example, prepreg. Prepreg is a flexible sheet material consisting of fiber, such as carbon fiber, glass fiber, and aramid fiber, mixed with uncured resin (e.g., thermoset resin, epoxy resin, etc.). Prepreg is inexpensive compared to a synthetic resin material such as polyimide and polyethylene terephthalate. The base layer 14 may also be made of an engineering plastic film (synthetic resin material). The base layer 14 and the first outer layer 11L may be bonded together by heating and pressing. The base layer 14 has a first surface 14a on the first outer layer 11L side and a second surface 14b opposite the first surface 14a. On the second surface 14b is provided a protective film 15 (protective layer, coating layer, coating, bump protective layer).

At least, during the process of S13, the base layer 14 is softer than the conductive portion 13. Accordingly, the conductive portion 13 passes through the base layer 14 while the base layer 14 is being placed on the first outer layer 11L, and the top portion 13b of the conductive portion 13 sticks out from the second surface 14b. As previously mentioned, the protective film 15, which is softer than the conductive portion 13, is provided on the second surface 14b. Thus, the top portion 13b of the conductive portion 13 sticking out from the second surface 14b is covered with the protective film 15.

Besides, at least, during the process of S13, the base layer 14 is softer than the conductive layer 12. Accordingly, in the structure in which the base layer 14 and the first outer layer 11L are bonded together, the conductive layer 12 is buried in the base layer 14 (the first surface 14a).

The base layer 14 is provided with an opening 16a (16) at a position corresponding to at least the one conductive layer 12. The opening 16 may be formed as a through hole, a cutout, or the like. The conductive layer 12 corresponding to the opening 16 is an example of the terminals 20 (connector terminals, connection points, contact points, conductors). The first surface 12a of the conductive layer 12 as the terminals 20 is an example of a contact surface 20a (exposed surface).

Then, as illustrated in FIG. 10, the protective film 15 is removed from the second surface 14b of the base layer 14 (S14).

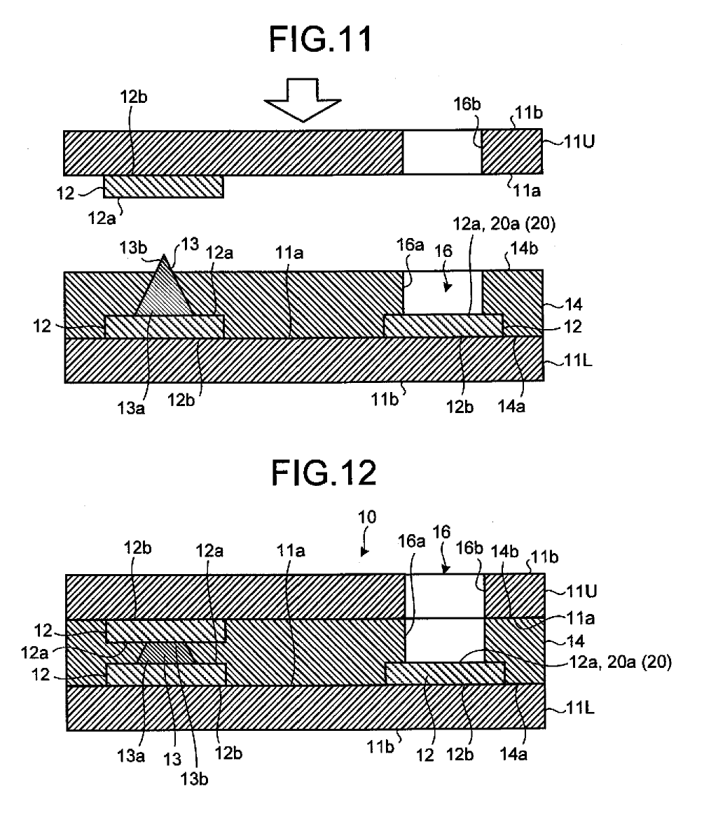

After that, as illustrated in FIGS. 11 and 12, the second outer layer 11U is placed on the second surface 14b of the base layer 14 from which the protective film 15 has been removed and bonded thereto (S15). The base layer 14 and the second outer layer 11U may be bonded together by heating and pressing. Before the process of S15, the conductive layer 12 has already been provided on the second outer layer 11U (S10), and a conductive layer pattern has already been formed (S11).

The second outer layer 11U has the first surface 11a on the base layer 14 side and the second surface 11b opposite the first surface 11a. On the first surface 11a, there is provided the conductive layer 12 at a position corresponding to the conductive portion 13. The top portion 13b of the conductive portion 13 is flattened out (crushed, pressed down) by the conductive layer 12 while the base layer 14 and the second outer layer 11U are bonded together. Flattening out the top portion 13b with the conductive layer 12 in this manner facilitates to achieve good conduction (contact) between the conductive portion 13 and the conductive layer 12. Besides, the second outer layer 11U is provided with an opening 16b. A combination of the opening 16b and the opening 16a of the base layer 14 forms the one opening 16. With the process from S10 to S15, the flexible printed wiring board 10 as illustrated in FIG. 12 can be obtained.

At least, during the process of S15, the base layer 14 is softer than the conductive layer 12. Accordingly, in the structure in which the base layer 14 and the second outer layer 11U are bonded together, the conductive layer 12 is buried in the base layer 14 (the second surface 14b). While FIGS. 5 to 12 illustrate an example in which the second outer layer 11U is bonded to the base layer 14 after the first outer layer 11L, it may be bonded to the base layer 14 before the first outer layer 11L, or the first outer layer 11L, the base layer 14, and the second outer layer 11U may be stacked in layers and bonded together at once. Further, there may be involved the process of increasing the connection strength among the first outer layer 11L, the base layer 14, and the second outer layer 11U after the first outer layer 11L and the second outer layer 11U are bonded to the base layer 14.

As described above, according to the first embodiment, the base layer 14 is bonded to the outer layer 11 provided with the conductive layer 12 on the first surface 11a on the base layer 14 side to obtain the flexible printed wiring board 10. On the other hand, in the conventional manufacturing method of the flexible printed wiring board 10 including the base layer 14 provided with the conductive layer 12 (conductive layer pattern) on the first surface 14a and the second surface 14b, after the conductive layer 12 is formed on the first surface 14a and the second surface 14b, the outer layer 11 is bonded to the first surface 14a and the second surface 14b. In the manufacturing method including the process of bonding two outer layers (the first outer layer 11L and the second outer layer 11U) to the surfaces 14a and 14b of the base layer 14 where a pattern of the conductive layer 12 is formed, manufacturing may be troublesome because, for example, it is difficult to handle the base layer 14 upon bonding. Further, in the conventional manufacturing method, it is often the case that an adhesive (adhesive layer) is used to bond the base layer 14 and the outer layer 11 together. An adhesive (adhesive layer) between the base layer 14 and the outer layer 11 is likely to make the flexible printed wiring board 10 thicker and less flexible.

Regarding this, according to the first embodiment, the conductive layer 12 (conductive layer pattern) is provided not to the base layer 14 but to the outer layer 11. Thus, for example, there is no layer with the conductive layer 12 formed on the both surfaces, which reduces troubles in manufacturing the flexible printed wiring board 10. Further, if the base layer 14 and the outer layer 11 are bonded together without an adhesive, the flexible printed wiring board 10 may be formed thinner. As a result, for example, the flexible printed wiring board 10 can be more flexible.

As described above, the base layer 14 is softer than the conductive layer 12 when bonded to the outer layer 11 (S13, S15). Accordingly, the conductive layer 12 is buried in the base layer 14 (the first surface 14a and the second surface 14b). The structure in which the conductive layer 12 is buried in the base layer 14 as illustrated in FIG. 12 may provide an evidence for that the flexible printed wiring board 10 is manufactured in the same manner as described in the first embodiment.

It can be understood from FIG. 11 that it is generally difficult to provide the conductive layer 12 to the position of the opening 16 in the surface 11a of the outer layer 11 on the base layer 14 side. Thus, the structure as illustrated in FIG. 12 in which the surface 12a of the conductive layer 12 opposite the surface 12b in contact with the outer layer 11 (in the first embodiment, for example, the first outer layer 11L) is exposed from the opening 16 may provide an evidence for that the flexible printed wiring board 10 is manufactured in the same manner as described in the first embodiment.

According to the first embodiment, the conductive portion 13 includes the base portion 13a on one side and the top portion 13b on the other side. The top portion 13b is thinner than the base portion 13a and comes in contact with the conductive layer 12. Thus, the top portion 13b is easily flattened out by the corresponding conductive layer 12 while the base layer 14 and the outer layer 11 are being bonded together. This facilitates to achieve good conduction (contact) between the top portion 13b and the conductive layer 12.

According to the first embodiment, the base layer 14 is made of prepreg, while the outer layer 11 is made of a synthetic resin material such as polyimide. Thus, the flexible printed wiring board 10 can be formed at a low cost. Generally, prepreg is a material with relatively low toughness. Therefore, if the base layer 14 is made of prepreg and the outer layer 11 is made of an engineering plastic material such as polyimide, the flexible printed wiring board 10 that is resistant to damage can be obtained at a low cost.

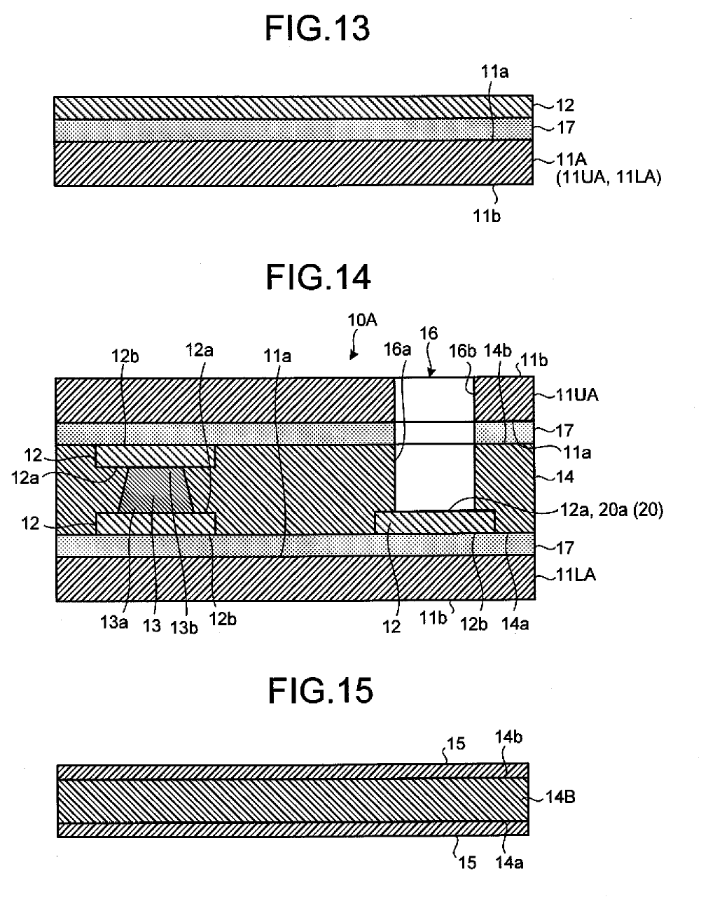

FIGS. 13 and 14 illustrates a flexible printed wiring board 10A according to a modification of the first embodiment. The flexible printed wiring board 10A of the modification can replace the flexible printed wiring board 10 of the first embodiment. In the modification, as illustrated in FIG. 13, the conductive layer 12 is bonded to the first surface 11a of an outer layer 11A (11LA, 11UA) via an adhesive layer 17 (adhesive portion, connection portion, connection layer, fourth layer, fourth portion, fourth area) containing an adhesive. For example, as in the first embodiment, etching is applied to the conductive layer 12 to form a pattern of the conductive layer 12 (conductive pattern, wiring pattern, wiring) on the adhesive layer 17. The base layer 14 and the two outer layers 11A (first outer layer 11LA and second outer layer 11UA) are bonded together by the adhesive layer 17. Thus, the flexible printed wiring board 10A as illustrated in FIG. 14 can be obtained. The adhesive layer 17 is an example of a fourth layer, a fourth portion, and a fourth area.

According to the modification also, the base layer 14 is bonded to the two outer layers 11A provided with the conductive layer 12 (conductive layer pattern) on the first surface 11a to obtain the flexible printed wiring board 10A. Thus, the same effect as in the first embodiment can be achieved. Besides, the adhesive layer 17 can be used to bond the outer layer 11A to the conductive layer 12 as well as to the base layer 14. This facilitates, for example, to reduce manufacturing processes and costs compared to the case where the outer layer 11A, the conductive layer 12, and the base layer 14 are bonded individually by an adhesive or the adhesive layer 17.

FIGS. 15 to 20 are cross-sectional views of a flexible printed wiring board 10B in a manufacturing process according to a second embodiment. The flexible printed wiring board 10B of the second embodiment can replace the flexible printed wiring board 10 of the first embodiment. As illustrated in FIGS. 15 to 19, in the second embodiment, a conductive portion 13B has a different structure and is formed in a different manner from the conductive portion 13 of the first embodiment.

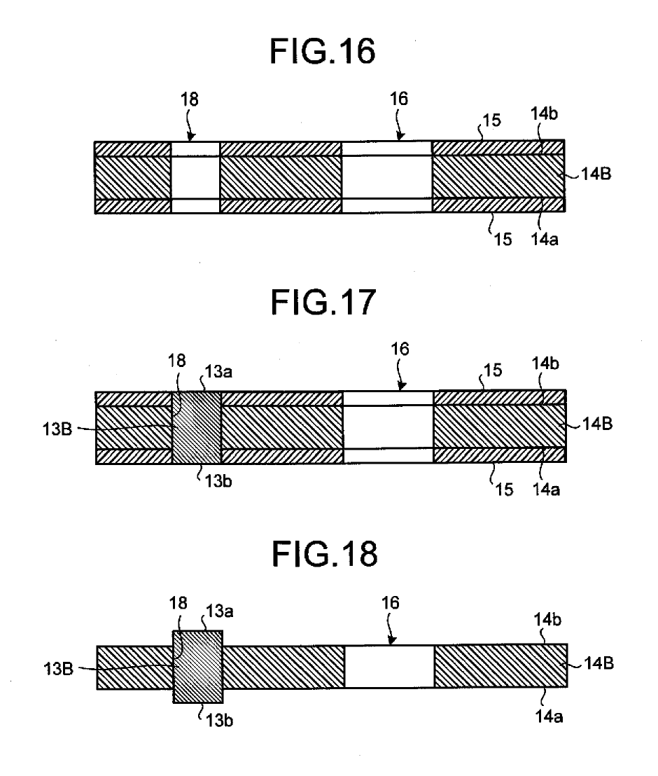

According to the second embodiment, as illustrated in FIG. 15, the first surface 14a and the second surface 14b of a base layer 14B is covered with the protective film 15. Then, as illustrated in FIG. 16, the base layer 14B covered with the protective film 15 is provided with openings 16 and 18. The opening 16 corresponds the terminals 20, i.e., the conductive layer 12 (see FIG. 20). Subsequently, as illustrated in FIG. 17, the conductive portion 13B is formed in the other opening 18. The conductive portion 13B may be made of conductive paste (e.g., silver paste, copper paste, etc.). The conductive portion 13B has, for example, a columnar shape where the portions 13a and 13b have substantially the same diameter (area).

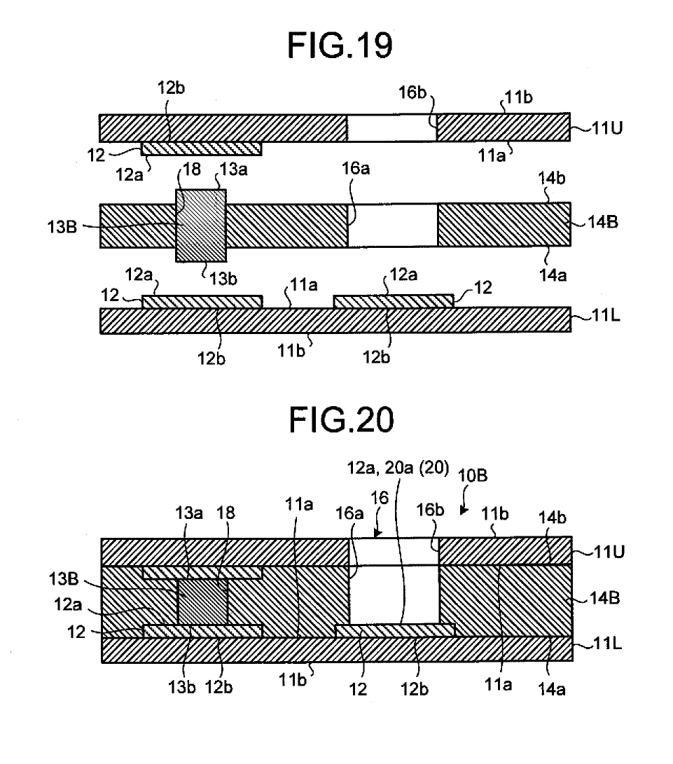

After that, as illustrated in FIG. 18, the protective film 15 is removed from the first surface 14a and the second surface 14b of the base layer 14B and, as illustrated in FIG. 19, the base layer 14B and the outer layer 11 (11L and 11U) are bonded together. The outer layer 11 may have the same structure as in the first embodiment. Besides, the base layer 14B and the outer layer 11 may be bonded together by heating and pressing as in the first embodiment. While the base layer 14B and the outer layer 11 are being bonded together, the conductive portion 13B made of conductive paste is pressed by the conductive layer 12 and is compressed. This facilitates to achieve reliable conduction (contact) between the conductive portion 13B and the conductive layer 12. Thus, the flexible printed wiring board 10B as illustrated in FIG. 20 can be obtained.

According to the second embodiment also, the base layer 14B is bonded to the two outer layers 11 (11L and 11U) provided with the conductive layer 12 (conductive layer pattern) on the first surface 11a to obtain the flexible printed wiring board 10B. Thus, the same effect as in the first embodiment can be achieved. Besides, the conductive portion 13B is made of conductive paste, which facilitates, for example, to achieve good conduction (contact) between the conductive portion 13B and the conductive layer 12. In addition, the base layer 14B provided with the conductive portion 13B is bonded to the outer layer 11. This facilitates, for example, to reduce manufacturing processes and costs.

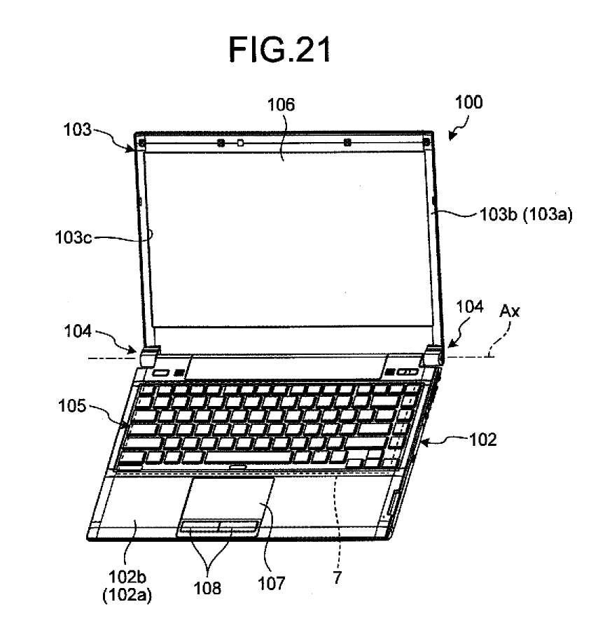

FIG. 21 illustrates an electronic device 100 according to a third embodiment. The flexible printed wiring board 10 (10, 10A, 10B) can be provided to the electronic device 100. The electronic device 100 is, for example, a notebook personal computer (PC). The electronic device 100 comprises a flat rectangular first body 102 and a flat rectangular second body 103. The first body 102 and the second body 103 are connected by a hinge 104 to be relatively rotatable about, for example, the rotation axis Ax between an open position illustrated in FIG. 21 and a closed position (not illustrated).

The first body 102 is provided with a keyboard 105, a pointing device 107, click buttons 108, and the like as input devices, which are exposed on a front surface 102b as the outer surface of a housing 102a (first housing) of the first body 102. The second body 103 is provided with a display 106 such as a liquid crystal display (LCD) as a display device (component). The display 106 is exposed from an opening 103c in a front surface 103b as the outer surface of a housing 103a (second housing) of the second body 103. In the open position as illustrated in FIG. 21, the keyboard 105, the display 106, the pointing device 107, the click buttons 108, and the like are exposed so that the user can use them. On the other hand, in the closed position (not illustrated), the front surface 102b closely faces the front surface 103b, and the keyboard 105, the display 106, the pointing device 107, the click buttons 108, and the like are hidden between the housings 102a and 103a.

The housing 102a of the first body 102 houses components (not illustrated) such as a circuit board assembly, a hard disk, a cooling fan, and the like. The circuit board assembly comprises the circuit board 7 having a central processing unit (CPU), a read only memory (ROM), a random access memory (RAM), and other components mounted thereon. The flexible printed wiring board 10 of the above embodiments or modification thereof is electrically connected to the circuit board 7 (not illustrated in FIG. 21). With the flexible printed wiring board 10, the electronic device 100 of the third embodiment can achieve the same effects as previously described.

The embodiments may be applied to any other electronic device comprising a flexible printed wiring board. In addition, the specifications (structure, type, direction, shape, size, length, width, thickness, height, number, arrangement, position, material, etc.) can be suitably modified regarding the TV receiver, the electronic device, the housing, the flexible printed wiring board, the inner layer, the base layer, the outer layer, the coating layer, the protective layer, the conductive layer, the opening, the conductive portion, the conductive bump, the conductive paste, the terminal, and the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television receiver comprising:
a housing;
a circuit board housed in the housing; and
a flexible printed wiring board configured to electrically connect to the circuit board, the flexible printed wiring board comprising:
an inner layer comprising a first surface and a second surface located opposite the first surface,
a first outer layer over the first surface of the inner layer,
a second outer layer over the second surface of the inner layer,
a first conductive layer in the first surface of the inner layer and in contact with the first outer layer,
a second conductive layer in the second surface of the inner layer and in contact with the second outer layer, and
a conductive portion configured to pass through the inner layer and electrically connect the first conductive layer and the second conductive layer.

2. The television receiver of claim 1, wherein the flexible printed wiring board is configured with an opening that exposes a surface of the first conductive layer or the second conductive layer opposite a surface in contact with the first outer layer or the second outer layer.

3. The television receiver of claim 1, wherein the conductive portion comprises a first end portion and a second end portion, the first end portion is configured to contact the first conductive layer or the second conductive layer and is thinner than the second end portion.

4. The television receiver of claim 1, wherein the conductive portion comprises conductive paste.

5. The television receiver of claim 1, wherein the inner layer comprises prepreg.

6. The television receiver of claim 1, wherein the first outer layer or the second outer layer comprises polyimide.

7. The television receiver of claim 1, wherein the inner layer, the first outer layer, and the second outer layer are configured to bond without an adhesive.

8. An electronic device comprising:
a housing; and
a flexible printed wiring board housed in the housing, the flexible printed wiring board comprising:
an inner layer with a first surface and a second surface located opposite the first surface,
a first outer layer over the first surface of the inner layer,
a second outer layer over the second surface of the inner layer,
a first conductive layer in the first surface of the inner layer and in contact with the first outer layer,
a second conductive layer in the second surface of the inner layer and in contact with the second outer layer, and
a conductive portion configured to pass through the inner layer and electrically connect the first conductive layer and the second conductive layer.

9. An electronic device comprising:
a housing;
an inner layer in the housing, the inner layer comprising a first surface and a second surface located opposite the first surface,
a first outer layer over the first surface of the inner layer,
a second outer layer over the second surface of the inner layer,
a first conductive layer in the first surface of the inner layer and in contact with the first outer layer,
a second conductive layer in the second surface of the inner layer and in contact with the second outer layer, and
a conductive portion configured to pass through the inner layer and electrically connect the first conductive layer and the second conductive layer.
